(19) United States
(12) Patent Application Publication
(10) Pub. No.: US 2026/0372120 A1
(43) Pub. Date: Nov. 19, 2026

(54) PACKAGING INTERPOSER BASED ON METAL CARRIER AND METHOD FOR MANUFACTURING SAME

(71) Applicant: SHANGHAI INSTITUTE OF MICROSYSTEM AND INFORMATION TECHNOLOGY, CHINESE ACADEMY OF SCIENCES, Shanghai (CN)

(72) Inventor: Kelaiti XIAO, Shanghai (CN)

(73) Assignee: SHANGHAI INSTITUTE OF MICROSYSTEM AND INFORMATION TECHNOLOGY, CHINESE ACADEMY OF SCIENCES, Shanghai (CN)

(21) Appl. No.: 19/136,904

(22) PCT Filed: Apr. 19, 2024
(86) PCT No.: PCT/CN2024/088910

§ 371 Date: Jun. 9, 2025

(30) Foreign Application Priority Data
Apr. 27, 2023 (CN) 202310467619.2

(51) Int. Cl. H10W 70/05; H10W 70/63; H10W 70/652; H10W 70/685

(52) U.S. Cl. CPC H10W 70/095; H10W 70/63; H10W 70/652; H10W 70/685

(57) ABSTRACT

The present disclosure provides a packaging interposer based on a metal carrier and a method for manufacturing the same. The metal carrier is used as a substrate of the packaging interposer, and the metal can be directly etched to form a blind via, which avoids the preparation of the blind via through a series of complex processes such as glue coating, exposure, development, dry etching, and wet stripping, as well as expensive equipment costs and material costs, thereby effectively reducing the process complexity and manufacturing costs. In addition, the metal carrier and the filling material in the blind via are both metals, and the CTE of the two metals are similar and the tensile strength is high. Additionally, forming a metal oxide passivation layer on the metal carrier through electroplating provides superior water absorption resistance and insulation performance compared to silicon dioxide, effectively enhancing the device's insulation property.

### FIELD OF TECHNOLOGY

The present disclosure belongs to the technical field of semiconductor packaging, and in particular to a packaging interposer based on a metal carrier and a method for manufacturing the same.

### BACKGROUND

As electronic products develop towards miniaturization, high performance, and high reliability, system integration is also increasing. Therefore, the traditional approach of improving performance by further reducing the feature size of integrated circuits and the line width of interconnection lines is constrained by the physical properties of materials and equipment processes. As a result, Moore's Law is facing increasing difficulty in sustaining its progression. At present, advanced packaging techniques include: Wafer Level Chip Scale Packaging (WLCSP), Fan-Out Wafer Level Package (FOWLP), Flip Chip, Package on Package (POP), etc. The 2.5D/3D integration technology based on Through-Silicon Via (TSV) has been widely regarded as the leading solution for future high-density packaging and an effective approach to transcend the limitations of Moore's Law.

The existing 2.5D/3D packaging structure generally includes a silicon interposer, which uses silicon as a carrier and metal pillars as interconnection lines for connecting the front and back sides. The via forming process requires processes such as coating, exposure, dry etching and wet stripping, which are complex and costly. In addition, annealing is required during the metal pillar machining. The release of metal stress leads to the isotropic growth of metal grains, resulting in a huge expansion around the silicon via. The low coefficient of thermal expansion (CTE), strength, and brittleness of silicon material can easily lead to fragmentation, affecting product yield and potentially damaging machine stability.

### SUMMARY

The present disclosure provides a packaging interposer based on a metal carrier and a method for manufacturing the same, thus solving the problems of a complicated preparation process and expensive equipment associated with interposers used for packaging. Furthermore, it addresses the issue of fragment generation, which negatively affects product yield and machine stability.

The method includes:
providing a metal carrier, wherein the metal carrier includes a first surface and a second surface opposite to the first surface;
etching from the first surface of the metal carrier along a thickness direction thereof to form one or more blind vias;
forming a metal oxide passivation layer on the first surface of the metal carrier and on bottom walls and side walls of the blind vias by an electroplating process;
filling the blind vias with a metal material, and performing an annealing process on the metal material to release metal stress to form metal electrical connection pillars;
forming a first redistribution layer on the first surface of the metal carrier, wherein the first redistribution layer is electrically connected with the metal electrical connection pillars;
thinning the metal carrier from the second surface of the metal carrier until the metal electrical connection pillars in the blind vias are exposed; and
forming a second redistribution layer on the second surface of the metal carrier, wherein the second redistribution layer is electrically connected with the metal electrical connection pillars.

Optionally, a process of forming the metal electrical connection pillars includes: first forming a conductive layer on a surface of the metal oxide passivation layer using a physical vapor deposition (PVD) process; filling the blind vias with a filling metal material using an electroplating process; then performing the annealing process at a high temperature above 600 °C to release metal stress; and finally performing a chemical mechanical polishing (CMP) process to planarize the first surface of the metal carrier until the metal oxide passivation layer is exposed.

Furthermore, a material of the conductive layer includes copper, gold and nickel, and the filling metal material is copper.

Optionally, a process of forming the metal oxide passivation layer includes: first forming a conductive layer on a surface of the metal oxide passivation layer using a PVD process; filling the blind vias with a filling metal material using an electroplating process; then performing the annealing process at a high temperature above 600 °C to release metal stress; and finally performing a CMP process to planarize the first surface of the metal carrier until the metal oxide passivation layer is exposed.

Furthermore, a material of the metal carrier is aluminium, and the electrolyte is sulfuric acid.

Optionally, the blind vias are formed by mechanical drilling or by laser etching.

Furthermore, after forming the blind vias, the method further comprises a step of cleaning the surface of the metal carrier, first performing alkaline cleaning and then performing acid cleaning.

Optionally, both the first redistribution layer and the second redistribution layer include a patterned dielectric layer and a patterned metal wiring layer.

The present disclosure further provides a packaging interposer based on a metal carrier including:
a metal carrier, wherein the metal carrier includes a first surface and a second surface opposite to the first surface;
one or more through-vias penetrating through the metal carrier;
a metal oxide passivation layer, wherein the metal oxide passivation layer is formed on the first surface of the metal carrier and bottom walls and side walls of the through-vias;
a metal electrical connection pillar, wherein the metal electrical connection pillars are formed on the metal oxide passivation layer of the through-vias and fill the through-vias;
a first redistribution layer, wherein the first redistribution layer is formed on the first surface of the metal carrier and electrically connected with the metal electrical connection pillars; and
a second redistribution layer, wherein the second redistribution layer is formed on the second surface of the metal carrier and electrically connected with the metal electrical connection pillars.

Optionally, a material of the metal carrier is aluminium or magnesium, and a material of the metal electrical connection pillars includes copper.

As described above, the packaging interposer based on the metal carrier and the method for manufacturing the same of the present disclosure use the metal carrier as the substrate of the packaging interposer, and can directly etch the metal to form the blind via, which avoids the preparation of the blind via through a series of complex processes such as coating, exposure, development, dry etching and wet stripping, as well as expensive equipment costs and material costs, thereby effectively reducing process complexity and manufacturing costs; in addition, the metal carrier and the filling material in the blind via are both metals, and the CTE of the two metals are similar and the tensile strength is high. This eliminates the issues of metal fragments and microcracks during the annealing process. Additionally, forming a metal oxide passivation layer on the metal carrier through electroplating provides superior water absorption resistance and insulation performance compared to silicon dioxide, effectively enhancing the device's insulation property.

### BRIEF DESCRIPTION OF THE DRAWINGS

FIGS. 1-14 are schematic diagrams showing a cross-sectional structure after each step is completed in an exemplary method for manufacturing a packaging interposer.

FIG. 15 is a schematic diagram showing a cross-sectional structure of a metal carrier provided in the method for manufacturing the packaging interposer based on the metal carrier of the present disclosure.

FIG. 16 is a schematic diagram showing a cross-sectional structure after etching to form blind vias in the method for manufacturing the packaging interposer based on the metal carrier of the present disclosure.

FIG. 17 is a schematic diagram showing a cross-sectional structure after cleaning the metal carrier in the method for manufacturing the packaging interposer based on the metal carrier of the present disclosure.

FIG. 18 is a schematic diagram showing a cross-sectional structure after forming a metal oxide passivation layer in the method for manufacturing the packaging interposer based on the metal carrier of the present disclosure.

FIG. 19 is a schematic diagram showing a cross-sectional structure after electroplating to form a filling metal material and annealing in the method for manufacturing the packaging interposer based on the metal carrier of the present disclosure.

FIG. 20 is a schematic diagram showing a cross-sectional structure after planarizing the filling metal material in the method for manufacturing the packaging interposer based on the metal carrier of the present disclosure.

FIG. 21 is a schematic diagram showing a cross-sectional structure after forming a first redistribution layer in the method for manufacturing the packaging interposer based on the metal carrier of the present disclosure.

FIG. 22 is a schematic diagram showing a cross-sectional structure after forming a second redistribution layer and metal bumps in the method for manufacturing the packaging interposer based on the metal carrier of the present disclosure.

### Reference Numerals

100 Metal carrier
101 First surface
102 Second surface
103 Blind vias
104 Metal oxide passivation layer
105 Filling metal material
106 Metal electrical connection pillars
107 First redistribution layer
108 Second redistribution layer
109 Patterned dielectric layer
110 Patterned metal wiring layer
111 Metal bumps
112 Burrs
113 Foreign matter
201 Silicon wafer
202 Photoresist layer
203 Patterned photoresist layer
204 Mask
205 Silicon blind via
206 Passivation layer
207 Metal layer
208 Crack
209 Front RDL wiring layer
210 Carrier plate
211 Back RDL wiring layer
212 Metal bumps

### DETAILED DESCRIPTION

The following describes the embodiments of the present disclosure through specific examples. Those skilled in the art can easily understand other advantages and effects of the present disclosure from the contents disclosed in this specification. The present disclosure may also be implemented or applied through other different specific embodiments, and the details in this specification may also be modified or changed in various ways based on different viewpoints and applications without departing from the spirit of the present disclosure.

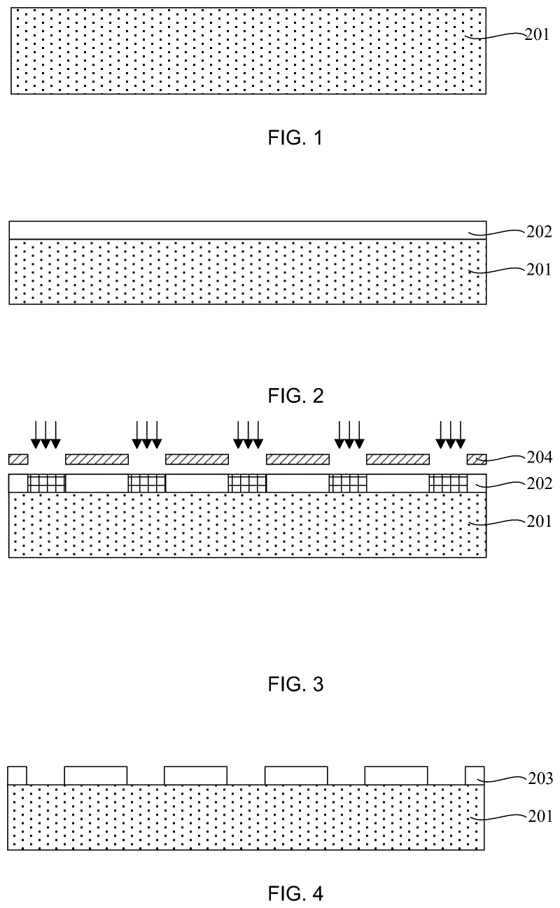

Please refer to FIGS. 1-22. It should be noted that the illustrations provided in this embodiment are only used to illustrate the basic concept of the present disclosure in a schematic manner, and therefore the illustrations only show components related to the present disclosure rather than being drawn according to the number, shape and size of components in actual implementation. In actual implementation, the type, quantity and proportion of each component may be changed arbitrarily, and the component layout may also be more complicated.

As shown in FIGS. 1-14, FIGS. 1-14 are schematic diagrams showing a cross-sectional structure after each step is completed in an exemplary method for manufacturing a packaging interposer. The method is specifically as follows:

As shown in FIG. 1, firstly, a silicon wafer 201 is generally selected and subjected to surface cleaning;

As shown in FIG. 2, a photoresist coating step is then performed, where a photoresist layer 202 is coated on the surface of the silicon wafer 201 by spraying, and the photoresist layer 202 of a certain thickness is coated as a barrier layer for subsequent dry etching.

As shown in FIG. 3, an exposure step is then performed, where a region to be etched on the silicon wafer 201 coated with a photoresist layer 202 is exposed or shielded as required using an exposure machine. A corresponding mask 204 is fabricated based on the selected photoresist (here, a positive photoresist is used, so the region to be etched is exposed).

As shown in FIG. 4, a development step is then performed, the photoresist layer 202 in the region to be etched is removed through a chemical reaction using a specific chemical solution to form a patterned photoresist layer 203;

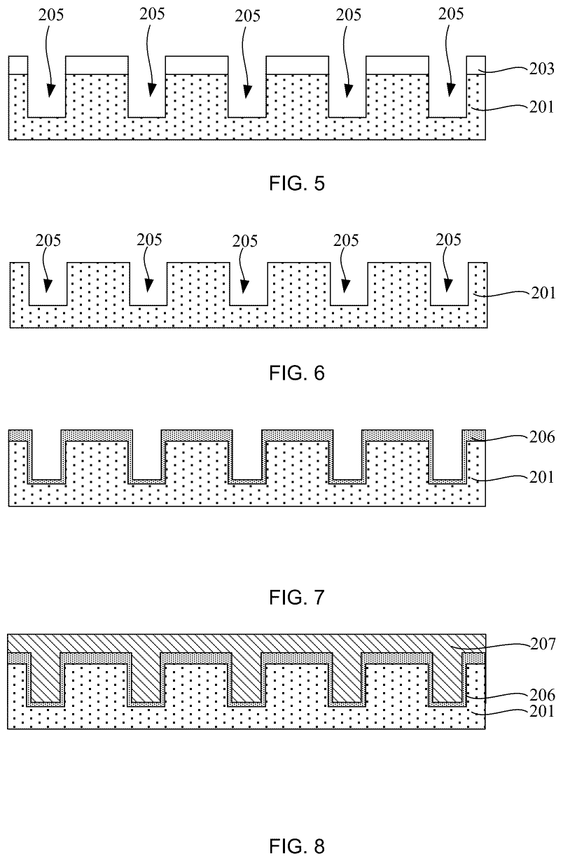

As shown in FIG. 5, a dry etching step is then performed using a vacuum etching machine, and the silicon is etched based on the patterned photoresist layer 203 using specific gases. A silicon blind via 205 with a desired depth is etched while maintaining an opening without significant changes;

As shown in FIG. 6, a photoresist stripping step is then performed by generally using a wet process to remove the patterned photoresist layer 203 through a chemical reaction with a specific solution.

As shown in FIG. 7, a passivation layer deposition step is then performed by depositing a passivation layer 206 on the surface of the above structure. Since silicon is a semiconductor and cannot directly contact the subsequently deposited metal, the passivation layer 206 needs to be deposited. Currently, a common process is to use plasma-enhanced chemical vapor deposition (PECVD for short). This process is not only expensive but also requires special highly toxic gases. Furthermore, the formed film layer easily absorbs water, which affects the insulation performance.

As shown in FIG. 8, a metal deposition step is then performed in the vias. After forming a conductive layer on the passivation layer 206 using PVD, a metal layer 207 is filled into the vias using an electroplating process.

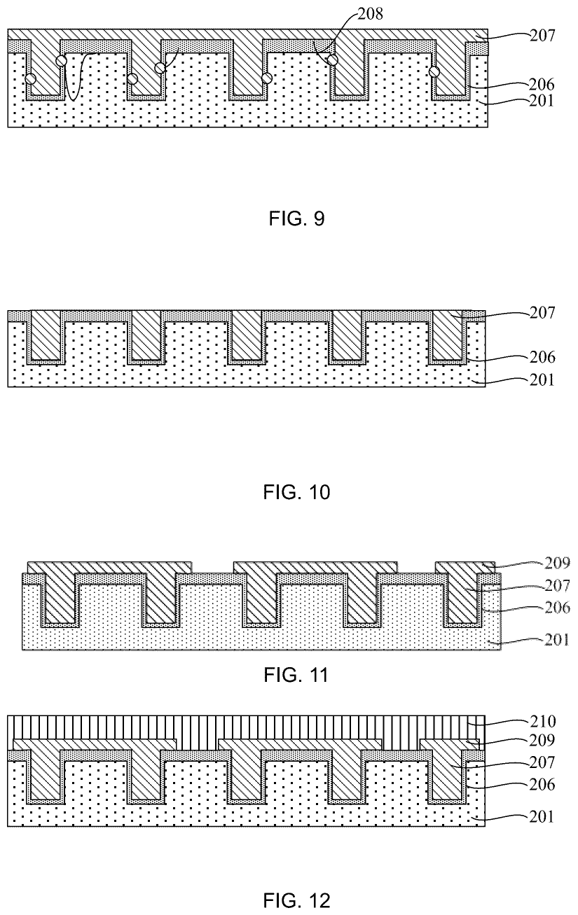

As shown in FIG. 9, an annealing step is then performed by annealing the structure to release the stress of the metal layer 207. The annealing process requires slow heating and cooling, and the metal stress is released at a high temperature above 600 °C. During stress release, metal grains grow anisotropically, synchronously, and unevenly. Due to the low strength of silicon, it is insufficient to withstand stress variations, often leading to hidden cracks or fragmentation in the silicon wafer, such as crack 208 in FIG. 9, which poses significant risks to subsequent processes and equipment

As shown in FIG. 10, a CMP process is then performed to remove the metal layer 207 on the surface of the silicon wafer 201 until the passivation layer 206 is exposed.

As shown in FIG. 11, a front-side wiring process step is then performed, and redistribution layer (RDL) wiring is performed on the front side using a bumping process to form a front RDL wiring layer 209.

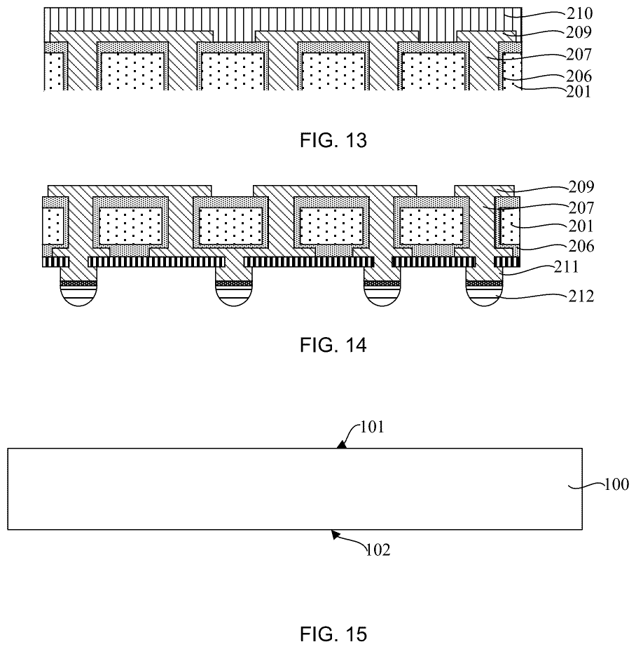

As shown in FIG. 12 and FIG. 13, a back-side exposure process step is then performed. As shown in FIG. 12, a carrier plate 210 is first bonded to the front side of the silicon wafer 201, and then the silicon is thinned to a certain thickness higher than a bottom surface of the silicon blind via 205 by a back thinning process; as shown in FIG. 13, the silicon wafer 201 is then thinned to a state where the silicon blind via 205 is exposed by dry etching.

As shown in FIG. 14, finally, a back-side wiring process step is performed. A back RDL wiring layer 211 and C4 metal bumps 212 are formed on a back side through a series of photolithography and electroplating processes to form the final product and remove the front-side carrier plate 211.

It can be seen from the above that the preparation process of the packaging interposer is very complicated and requires the use of expensive equipment. In addition, the annealing process is prone to producing fragments, resulting in unstable product structure quality, making the manufacturing cost of the interposer high, the efficiency low and the quality unstable. Accordingly, this embodiment provides a method for manufacturing a packaging interposer based on a metal carrier, and the method comprises the following steps:
S1: providing a metal carrier, wherein the metal carrier includes a first surface and a second surface opposite to the first surface;
S2: etching the first surface of the metal carrier along a thickness direction thereof to form one or more blind vias;
S3: forming a metal oxide passivation layer on the first surface of the metal carrier and on bottom walls and side walls of the blind vias by an electroplating process;
S4: filling the blind vias with a metal material, and performing an annealing process on the metal material to release metal stress to form metal electrical connection pillars;
S5: forming a first redistribution layer on the first surface of the metal carrier, wherein the first redistribution layer is electrically connected with the metal electrical connection pillars;
S6: thinning the metal carrier from the second surface of the metal carrier until the metal electrical connection pillars in the blind vias are exposed;
S7: forming a second redistribution layer on the second surface of the metal carrier, wherein the second redistribution layer is electrically connected with the metal electrical connection pillars.

The method for manufacturing the packaging interposer based on the metal carrier of the present disclosure adopts the metal carrier as the substrate of the packaging interposer, and the metal can be directly etched to form the blind vias, which avoids the manufacturing of the blind vias through a series of complex processes such as coating, exposure, development, dry etching and wet stripping, as well as expensive equipment costs and material costs, thereby effectively reducing process complexity and manufacturing costs; in addition, the metal carrier and the filling material in the blind vias are both metals, and the CTE of the two metals are similar and the tensile strength is high. This eliminates the issues of metal fragments and microcracks during the annealing process. Additionally, forming a metal oxide passivation layer on the metal carrier through electroplating provides superior water absorption resistance and insulation performance compared to silicon dioxide, effectively enhancing the device's insulation property.

The method for manufacturing the packaging interposer based on the metal carrier of this embodiment is described in detail below with reference to the specific drawings.

As shown in FIG. 15, step S1 is first performed by providing a metal carrier 100. The metal carrier 100 has a first surface 101 and a second surface 102 opposite to the first surface.

It should be noted here that the first surface 101 and the second surface 102 only represent that the metal carrier 100 has two opposite surfaces. If one surface is defined as the first surface, the other opposite surface is defined as the second surface, and the first and the second have no specific meanings. In addition, the thickness of the metal carrier 100 is selected according to actual needs. The incoming material may be thinned or not. The specific situation shall be selected and no excessive restrictions shall be made here.

For example, the metal carrier 100 may be made of any material suitable for manufacturing a packaging interposer, taking into account the following factors: high hardness, easy and safe machining, and good insulation performance of the metal oxide passivation layer formed by electroplating. For example, an aluminium material or a magnesium material. Based on comprehensive consideration, in this embodiment, aluminium is preferably selected as the material of the metal carrier 100.

As shown in FIG. 17, step S2 is then performed by forming one or more blind vias 103 by etching the first surface 101 of the metal carrier 100 along its thickness direction.

The depth, diameter, shape, count, and other parameters of the blind vias 103 are set according to actual packaging requirements.

As a preferred example, since the metal carrier 100 is used, the metal carrier 100 can be directly etched, for example, by using a mechanical drill to etch and form the blind vias 103 or by using laser etching to form the blind vias 103. Specifically, according to the diameter requirement of the blind vias 103, a laser spot diameter is adjusted or a mechanical drill of corresponding diameter is selected, and a laser energy and time or a pressing height of the mechanical drill is adjusted to produce the blind vias 103 that meets the requirements on the metal carrier 100. To increase efficiency, the count of the drill or laser heads can also be increased.

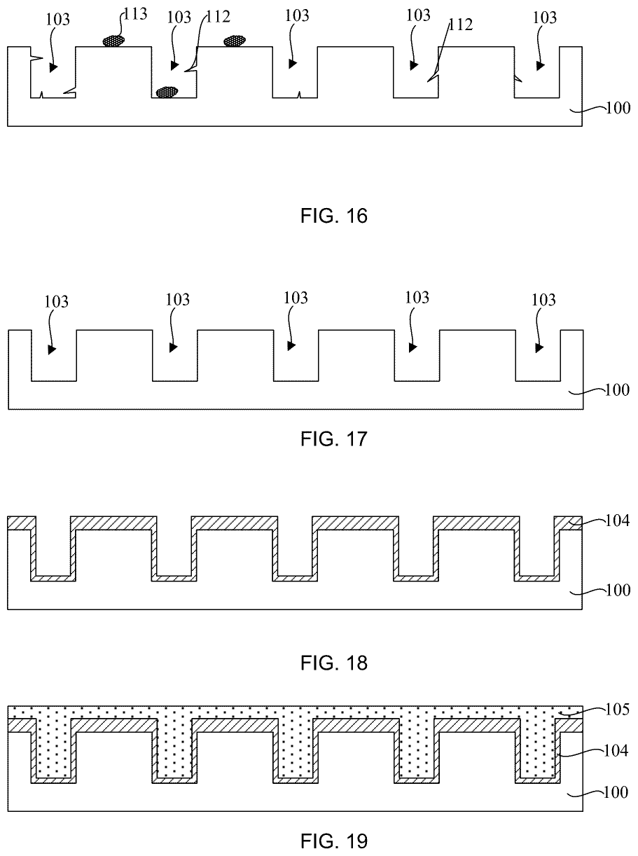

As shown in FIG. 16, as a preferred example, after the metal carrier 100 is etched to form the blind vias 103, byproducts such as foreign matter 113 on the surface of the metal carrier 100 and burrs 112 inside the blind vias 103 may be formed, which will affect the uniformity of the metal oxide passivation layer formed by subsequent electroplating. Therefore, it is best to clean it with a chemical solution, first with an alkaline solution such as a sodium hydroxide solution and then with an acid solution such as a dilute sulfuric acid solution, so that the surface of the metal carrier 100 forms a bright and clean surface.

As shown in FIG. 18, step S3 is then performed by forming a metal oxide passivation layer 104 on the first surface 101 of the metal carrier 100 and the bottom walls and the side walls of the blind vias 103 by using an electroplating process.

During the electroplating process, surfaces of the metal carrier 100 other than the first surface are sealed and protected, and only the first surface is exposed for electroplating. Specifically, first, the metal carrier 100 formed with the blind vias 103 is used as an anode, an inert metal is used as a cathode, and the acidic solution is used as an electrolyte. The metal carrier 100 is completely immersed in the electrolyte, and upon applying an electric current, the metal oxide passivation layer 104 is formed on the first surface 101 of the metal carrier 100 and the bottom walls and the side walls of the blind vias 103. Preferably, in this embodiment, the material of the metal carrier 100 is aluminium, and the sulfuric acid is used as the electrolyte during the electroplating process. When electricity is applied, the metal carrier 100 is oxidized to form an insulating metal oxide layer, with aluminium oxidized into ions. When current passes through, hydrogen is precipitated on the cathode, and oxygen (including molecular oxygen, atomic oxygen and ionic oxygen) is precipitated on the anode, usually represented by O2 in the reaction. The aluminium serving as the anode is oxidized by the oxygen precipitated thereon to form an anhydrous aluminium oxide film.

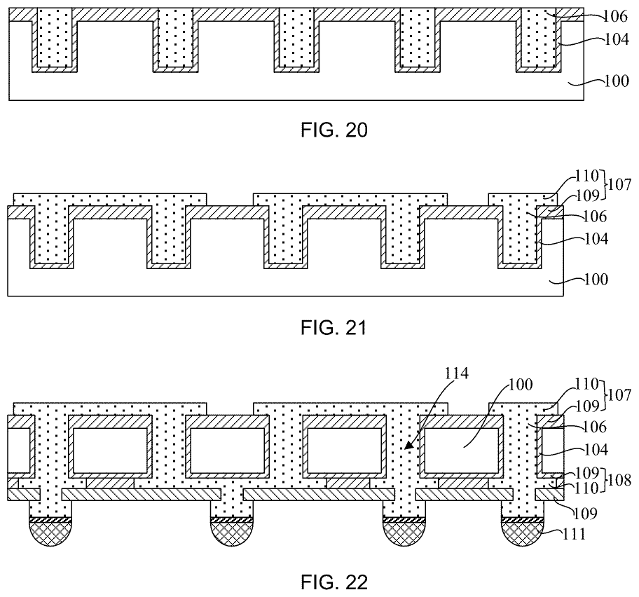

As shown in FIG. 19 and FIG. 20, step S4 is then performed by filling the blind vias 103 with a metal material, and annealing the metal material 105 to release the metal stress, so as to form metal electrical connection pillars 106.

As a preferred example, the process of forming the metal electrical connection pillars 106 includes: as shown in FIG. 19, first, forming a conductive layer (not shown in the figure) on the surface of the metal oxide passivation layer 104 using a PVD process. The material of the conductive layer is selected from copper, gold and nickel, which is generally a stacked structure of these materials, such as a stacked structure of a gold layer, a nickel layer, and a copper layer. Then filling the blind vias 103 with a filling metal material 105 using the electroplating process. The filling metal material 105 is generally selected to be copper; as shown in FIG. 19, then performing the annealing process at a high temperature above 600 °C. The process requires slow heating and cooling to release the metal stress; as shown in FIG. 20, finally, performing a CMP process to planarize the first surface of the metal carrier until the metal oxide passivation layer is exposed. Since the metal carrier 100 has high strength and a small CTE difference with the metal in the blind vias, there is no risk of cracking during the annealing process.

As shown in FIG. 21, step S5 is then performed by forming a first redistribution layer 107 on the first surface 101 of the metal carrier 100. The first re-distribution layer 107 is electrically connected with the metal electrical connection pillars 106.

As an example, the first redistribution layer 107 includes a patterned dielectric layer 109 and a patterned metal wiring layer 110. The process of forming the first redistribution layer 107 includes: forming a dielectric layer on the first surface 101 of the metal carrier 100, and etching the dielectric layer using conventional photolithography and etching processes to form the patterned dielectric layer 109; forming a metal wiring layer on the patterned dielectric layer 109 and the exposed first surface 101 of the metal carrier 100, and patterning it to form the patterned metal wiring layer 110. It should be noted here that the first redistribution layer 107 can be multiple layers according to actual needs, the method for manufacturing each layer of the first redistribution layer 107 is the same, and the above method can be used.

As shown in FIG. 22, step S6 is then performed by thinning the metal carrier 100 from the second surface 102 of the metal carrier 100 until the metal electrical connection pillars 106 in the blind vias 103 are exposed. After thinning, the blind vias 103 become through-vias 114 penetrating through the metal carrier 100.

For example, a carrier plate is bonded to the surface of the first redistribution layer 107 before thinning the metal carrier 100. After the carrier plate is bonded, the back-side exposure process is achieved by the thinning process without the need for a complex and repetitive multi-step CMP process.

As shown in FIG. 22, step S7 is finally performed by forming a second redistribution layer 108 on the second surface 102 of the metal carrier 100. The second redistribution layer 108 is electrically connected with the metal electrical connection pillars 106.

For example, the second redistribution layer 108 includes a patterned dielectric layer 109 and a patterned metal wiring layer 110. The process of forming the second redistribution layer 108 includes: forming a dielectric layer on the second surface 102 of the metal carrier 100, and etching the dielectric layer using conventional photolithography and the etching processes to form the patterned dielectric layer 109; forming a metal wiring layer on the patterned dielectric layer 109 and the exposed second surface 102 of the metal carrier 100, and patterning it to form the patterned metal wiring layer 110. It should be noted here that the second redistribution layer 108 can be multiple layers according to actual needs, the method for manufacturing each layer of the second redistribution layer 108 is the same, and the above method can be used.

As shown in FIG. 22, for example, after the second redistribution layer 108 is formed, the method further includes forming metal bumps 111 on the second redistribution layer 108. The metal bumps 111 include one of a gold-tin solder ball, a silver-tin solder ball, and a copper-tin solder ball, or the metal bumps 111 include a metal pillar and a solder ball formed on the metal pillars. Preferably, the metal pillars are copper pillars or nickel pillars. In this embodiment, the metal bumps 111 are gold-tin solder balls, and the manufacturing steps include: first forming a gold-tin layer on the surface of the second redistribution layer 108, and then using a high-temperature reflow process to reflow the gold-tin layer into a spherical shape, and forming the gold-tin solder balls after cooling; or using a ball planting process to form the gold-tin solder balls.

As shown in FIG. 22, for example, the carrier plate is removed after the final packaging interposer is formed.

As shown in FIG. 22, this embodiment further provides a packaging interposer based on a metal carrier, and the packaging interposer can be prepared using the above method. The beneficial effects that can be achieved by the packaging interposer can be found in the above method, which are not described in detail below. The packaging interposer comprises:
the metal carrier 100 including the first surface 101 and the second surface 102 opposite to the first surface;
one or more through-via 114 penetrating through the metal carrier;
the metal oxide passivation layer 104 formed on the first surface 101 of the metal carrier 101 and the bottom wall and the side wall of the through-vias 114;
the metal electrical connection pillar 106 formed on the metal oxide passivation layer 104 of the through-vias 114 and filling the through-vias 114;
the first redistribution layer 107 formed on the first surface 101 of the metal carrier 100, wherein the first redistribution layer 107 is electrically connected with the metal electrical connection pillars 106;
the second redistribution layer 108 formed on the second surface 102 of the metal carrier 100, wherein the second redistribution layer 108 is electrically connected with the metal electrical connection pillars 106.

For example, the material of the metal carrier 100 is aluminium or magnesium, and the material of the metal electrical connection pillars 106 is copper.

In summary, the present disclosure provides the packaging interposer based on the metal carrier and the method for manufacturing the same. The metal carrier is used as the substrate of the packaging interposer, and the metal can be directly etched to form the blind vias, which avoids the preparation of the blind vias through a series of complex processes such as coating, exposure, development, dry etching and wet stripping, as well as expensive equipment costs and material costs, thereby effectively reducing process complexity and manufacturing costs; in addition, the metal carrier and the filling material in the blind vias are both metals, and the CTE of the two metals are similar and the tensile strength is high. This eliminates the issues of metal fragments and microcracks during the annealing process. Additionally, forming a metal oxide passivation layer on the metal carrier through electroplating provides superior water absorption resistance and insulation performance compared to silicon dioxide, effectively enhancing the device's insulation property. Therefore, the present disclosure effectively overcomes various shortcomings in the related art and has high industrial utilization value.

The above embodiments are only used to illustrate the principles and effects of the present disclosure, and are not intended to limit the present disclosure. Anyone skilled in the art can modify or change the above embodiments without departing from the spirit and scope of the present disclosure. Therefore, all equivalent modifications or changes made by those skilled in the art without departing from the spirit and technical ideas disclosed by the present disclosure should still be covered by the claims of the present disclosure.

What is claimed is:

1. A method for manufacturing a packaging interposer based on a metal carrier, comprising:
providing a metal carrier, wherein the metal carrier comprises a first surface and a second surface opposite to the first surface;
etching from the first surface of the metal carrier along a thickness direction thereof to form one or more blind vias;
forming a metal oxide passivation layer on the first surface of the metal carrier and on bottom walls and side walls of the blind vias by an electroplating process;
filling the blind vias with a metal material, and performing an annealing process on the metal material to release metal stress to form metal electrical connection pillars;
forming a first redistribution layer on the first surface of the metal carrier, wherein the first redistribution layer is electrically connected with the metal electrical connection pillars;
thinning the metal carrier from the second surface of the metal carrier until the metal electrical connection pillars in the blind vias are exposed; and
forming a second redistribution layer on the second surface of the metal carrier, wherein the second redistribution layer is electrically connected with the metal electrical connection pillars.

2. The method for manufacturing the packaging interposer based on the metal carrier according to claim 1, wherein a process of forming the metal electrical connection pillars comprises: first forming a conductive layer on a surface of the metal oxide passivation layer using a PVD process; filling the blind vias with a filling metal material using an electroplating process; then performing the annealing process at a high temperature above 600 °C to release metal stress; and finally performing a CMP process to planarize the first surface of the metal carrier until the metal oxide passivation layer is exposed.

3. The method for manufacturing the packaging interposer based on the metal carrier according to claim 2, wherein a material of the conductive layer comprises copper, gold and nickel, and the filling metal material is copper.

4. The method for manufacturing the packaging interposer based on the metal carrier according to claim 1, wherein a process of forming the metal oxide passivation layer comprises: first using the metal carrier provided with the blind vias as an anode, an inert metal as a cathode, and an acidic solution as an electrolyte, completely immersing the metal carrier into the electrolyte,, and upon applying an electric current,, forming the metal oxide passivation layer on the first surface of the metal carrier and the bottom walls and the side walls of the blind vias.

5. The method for manufacturing the packaging interposer based on the metal carrier according to claim 4, wherein a material of the metal carrier is aluminium, and the electrolyte is sulfuric acid.

6. The method for manufacturing the packaging interposer based on the metal carrier according to claim 1, wherein the blind vias are formed by mechanical drilling or by laser etching.

7. The method for manufacturing the packaging interposer based on the metal carrier according to claim 6, wherein after forming the blind vias, the method further comprises a step of cleaning the surface of the metal carrier, first performing alkaline cleaning and then performing acid cleaning.

8. The method for manufacturing the packaging interposer based on the metal carrier according to claim 1, wherein both the first redistribution layer and the second redistribution layer comprise a patterned dielectric layer and a patterned metal wiring layer.

9. A packaging interposer based on a metal carrier, comprising:
a metal carrier, wherein the metal carrier comprises a first surface and a second surface opposite to the first surface;
one or more through-vias penetrating through the metal carrier;
a metal oxide passivation layer, wherein the metal oxide passivation layer is formed on the first surface of the metal carrier and bottom walls and side walls of the through-vias;
metal electrical connection pillars, wherein the metal electrical connection pillars are formed on the metal oxide passivation layer of the through-vias and fill the through-vias;
a first redistribution layer, wherein the first redistribution layer is formed on the first surface of the metal carrier and electrically connected with the metal electrical connection pillars; and
a second redistribution layer, wherein the second redistribution layer is formed on the second surface of the metal carrier and electrically connected with the metal electrical connection pillars.

10. The packaging interposer based on the metal carrier according to claim 9, wherein a material of the metal carrier is aluminium or magnesium, and a material of the metal electrical connection pillars comprises copper.
